(19) United States
(12) Patent Application Publication
(10) Pub. No.: US 2024/0290930 A1
(43) Pub. Date: Aug. 29, 2024

(54) DISPLAY DEVICE

(71) Applicant: LG DISPLAY CO., LTD., Seoul (KR)

(72) Inventors: Eunjeong YANG, Goyang-si (KR); Jaewon RYU, Seoul (KR); DaeYun KIM, Yongin-si (KR)

(73) Assignee: LG DISPLAY CO., LTD., Seoul (KR)

(21) Appl. No.: 18/588,222

(22) Filed: Feb. 27, 2024

(30) Foreign Application Priority Data
Feb. 28, 2023 (KR) 10-2023-0027206

(51) Int. Cl. H01L 33/64; H01L 25/075; H05K 7/20

(52) U.S. Cl. CPC H01L 33/642; H01L 25/0753; H05K 7/20963

(57) ABSTRACT

A display device includes a display panel, a cover bottom disposed on a rear surface of the display panel, and a printed circuit board disposed on a rear surface of the cover bottom and including a plurality of elements to drive the display panel, wherein the cover bottom includes a heat dissipating portion disposed in the cover bottom, and the printed circuit board is disposed on the heat dissipating portion, and one or more air gaps are formed between the heat dissipating portion and at least one of the display panel and the printed circuit board.

### CROSS-REFERENCE TO RELATED APPLICATION

This application claims the priority of Korean Patent Application No. 10-2023-0027206 filed on Feb. 28, 2023, which is hereby incorporated by reference in its entirety.

### BACKGROUND

### Field of the Disclosure

The present disclosure relates to a display device, and more particularly, to a display device using a light emitting diode (LED).

### Description of the Background

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied. Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device.

Further, the LED has a fast lighting speed, excellent luminous efficiency, and a strong impact resistance so that a stability is excellent and an image having a high luminance may be displayed.

### SUMMARY

Accordingly, the present disclosure is to provide a display device which reduces the influence on the display panel due to the heat generated on a printed circuit board.

The present disclosure is also to provide a display device which reduces a quantity of heat concentrated on one part by uniformly distributing heat generated from the printed circuit board.

Further, the present disclosure is to provide a display device which provides air layers in the vicinity of an electronic component which generates high heat to remove or reduce the influence on an adjacent display panel or other components of the display device due to the high heat.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings. The present disclosure is not limited to the above-mentioned and other features, which are not mentioned above, may be clearly understood by those skilled in the art from the following descriptions.

To achieve these and other advantages and in accordance with the present disclosure, as embodied and broadly described, a display device includes a display panel, a cover bottom disposed on a rear surface of the display panel, and a printed circuit board disposed on a rear surface of the cover bottom and including a plurality of elements to drive the display panel, wherein the cover bottom includes a heat dissipating portion disposed in the cover bottom, and the printed circuit board is disposed on the heat dissipating portion, and one or more air gaps are formed between the heat dissipating portion and at least one of the display panel and the printed circuit board.

In another aspect of the present disclosure, a display device includes a display panel, a cover bottom disposed on the display panel, and a printed circuit board disposed on the cover bottom, wherein the cover bottom includes a convex portion protruding towards the printed circuit board, and the convex portion accommodates at least one air gap.

In a further aspect of the present disclosure, display device includes a display panel, a cover bottom disposed on the display panel, a printed circuit board disposed on the cover bottom; and a highest heat generating element disposed on the printed circuit board, wherein the cover bottom includes at least one of a convex portion protruding towards the printed circuit board and a concave portion protruding towards the display panel, and each of the convex portion and the concave portion accommodates an air gap.

Other detailed matters of the exemplary aspects are included in the detailed description and the drawings.

According to the exemplary aspect of the present disclosure, the display device may reduce the influence on the display panel due to the heat generated from the printed circuit board.

According to the exemplary aspect of the present disclosure, the display device disperses the heat generated in the printed circuit board to the entire area of the display device so that the heat is not concentrated on one part.

Further, according to the exemplary aspect of the present disclosure, in the display device, one or a plurality of air layers is provided in the vicinity of the printed circuit board which generates high heat so that the influence of the heat between the component of the display device which is sensitive to the heat and the printed circuit board may be blocked or minimized by means of the air layer.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary aspect of the present disclosure;

FIG. 2A is a partial cross-sectional view of a display device according to an exemplary aspect of the present disclosure;

FIG. 2B is a perspective view of a tiling display device according to an exemplary aspect of the present disclosure;

FIG. 3 is a plan view of a display panel of a display device according to an exemplary aspect of the present disclosure;

FIG. 4 is a cross-sectional view of a display device according to an exemplary aspect of the present disclosure;

FIG. 5 is an exploded perspective view of a display device according to an exemplary aspect of the present disclosure;

FIG. 6 is a rear view of a display device according to an exemplary aspect of the present disclosure;

FIG. 7 is a cross-sectional view taken along line VII-VII′ of FIG. 6;

FIG. 8 is a cross-sectional view taken along line VIII-VIII′ of FIG. 6;

FIG. 9A is a temperature measurement result of a display device according to a comparative aspect; and

FIG. 9B is a temperature measurement result of a display device according to an exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be disposed directly on another element or layer, or a further layer or element may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, a present disclosure will be described in detail with reference to accompanying drawings.

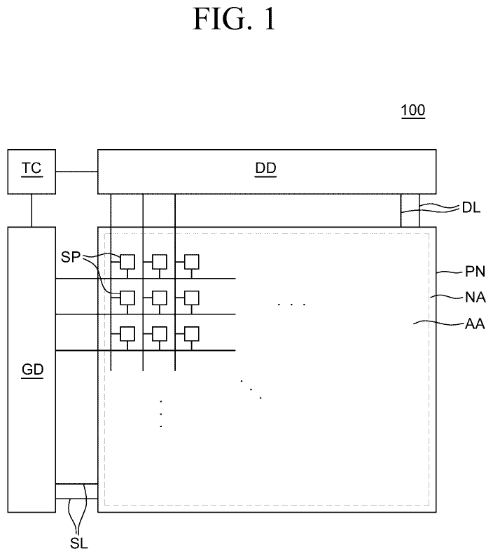

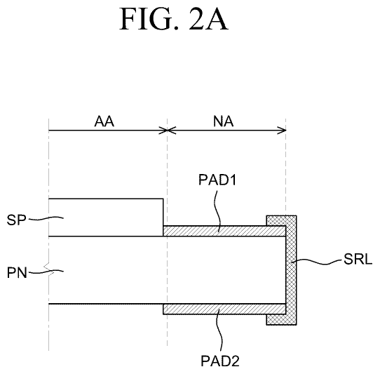

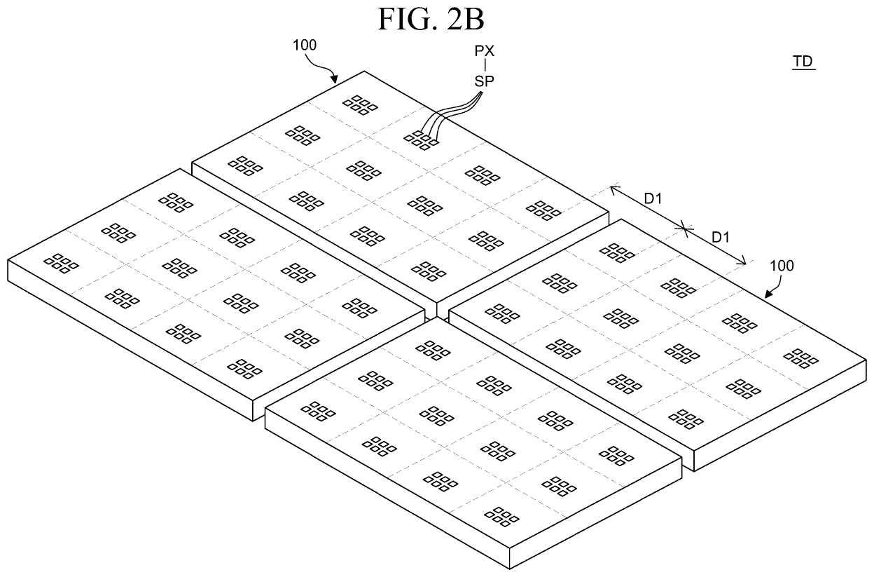

FIG. 1 is a schematic diagram of a display device according to an exemplary aspect of the present disclosure. FIG. 2A is a partial cross-sectional view of a display device according to an exemplary aspect of the present disclosure. FIG. 2B is a perspective view of a tiling display device according to an exemplary aspect of the present disclosure. In FIG. 1, for the convenience of description, among various components of the display device 100, only a display panel PN, a gate driver GD, a data driver DD, a timing controller TC, and a plurality of sub pixels SP are illustrated.

Referring to FIG. 1, the display device 100 includes the plurality of sub pixels SP disposed in the display panel PN, the gate driver GD and the data driver DD which supply various signals to the display panel PN, and the timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enables signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and the non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel PX. In each of the plurality of sub pixels SP, a light emitting diode, a thin film transistor for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of wiring lines which transmits various signals to the plurality of sub pixels SP is disposed. For example, the plurality of wiring lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL extends in one direction in the active area AA to be connected to the plurality of sub pixels SP and the plurality of data lines DL extends in a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, a driving IC, such as a gate driver IC and a data driver IC, or the like may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board. The data driver DD and the timing controller TC may be electrically connected to the display panel PN by bonding the flexible film and the printed circuit board to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel with substantially no bezel may be implemented.

Specifically, referring to FIGS. 2A and 2B, in the non-active area NA of the display panel PN, a plurality of pad electrodes for transmitting various signals to the plurality of sub pixels SP is disposed. For example, in the non-active area NA on the front surface of the display panel PN, a first pad electrode PAD1 which transmits a signal to the plurality of sub pixels SP is disposed. In the non-active area NA on the rear surface of the display panel PN, a second pad electrode PAD2 which is electrically connected to a driving component, such as a flexible film and the printed circuit board, is disposed. That is, on the front surface of the display panel PN on which images are displayed, only a pad area of the non-active area NA in which the first pad electrode PAD1 is disposed may be formed at minimum.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL may electrically connect a first pad electrode PAD1 on the front surface of the display panel PN and a second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize an area of the non-active area NA on the front surface of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a scam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, a distance D1 between pixels PX between the display devices 100 is constantly configured to minimize the seam area.

However, FIGS. 2A and 2B are illustrative so that the display device 100 according to the exemplary aspect of the present disclosure may be a general display device 100 with a bezel, but is not limited thereto.

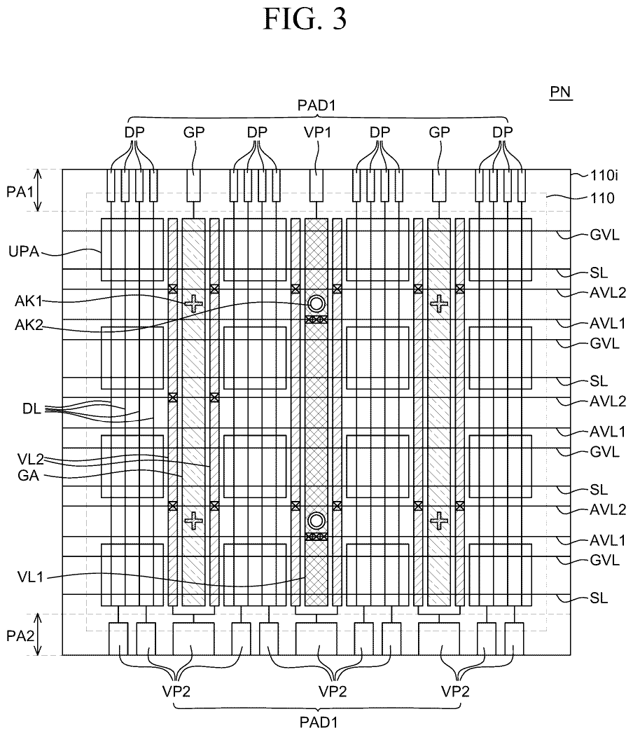

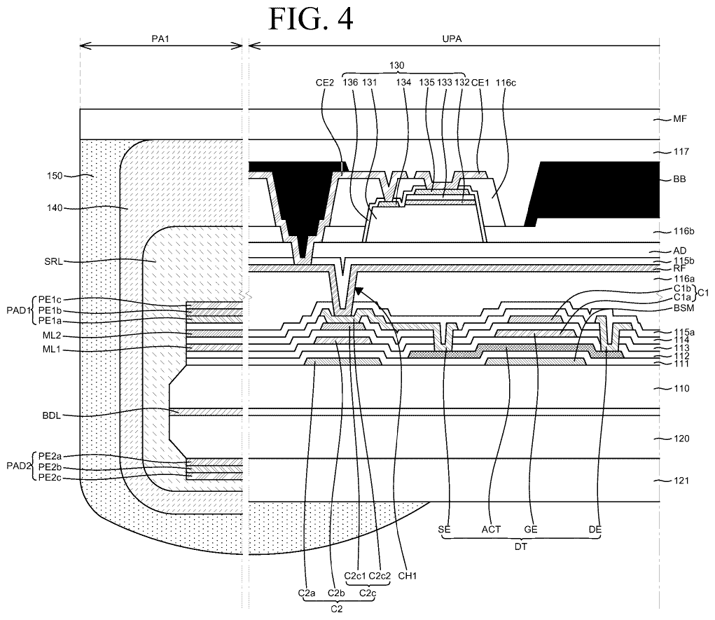

FIG. 3 is a plan view of a display panel of a display device according to an exemplary aspect of the present disclosure. FIG. 4 is a cross-sectional view of a display device according to an exemplary aspect of the present disclosure.

First, referring to FIGS. 3 and 4, the display panel PN includes a first substrate 110. The first substrate 110 is a substrate which supports components disposed above the display device 100 and may be an insulating substrate. A plurality of pixels PX is formed on the first substrate 110 to display images. For example, the first substrate 110 may be formed of glass or resin. Further, the first substrate 110 may include polymer or plastic. In some exemplary aspects, the first substrate 110 may be formed of a plastic material having flexibility.

In the first substrate 110, a plurality of pixel areas UPA, a plurality of gate driving areas GA, and a plurality of pad areas PA1 and PA2 are disposed. Among them, the plurality of pixel areas UPA and the plurality of gate driving areas GA may be included in the active area AA of the display panel PN.

First, the plurality of pixel areas UPA is areas in which the plurality of pixels PX is disposed. The plurality of pixel areas UPA may be disposed by forming a plurality of rows and a plurality of columns. Each of the plurality of pixels PX disposed in the plurality of pixel areas UPA includes a plurality of sub pixels SP. Each of the plurality of sub pixels SP includes a light emitting diode 130 and a pixel circuit to independently emit light. The plurality of sub pixels SP may include a plurality of sub pixels SP which emits different color light. For example, the plurality of sub pixels SP may include a red sub pixel, a blue sub pixel, and a green sub pixel, but is not limited thereto.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. At this time, the gate driver may include, for example, a plurality of transistors and/or capacitors. Here, active layers of the plurality of transistors may be formed of a semiconductor material, such as an oxide semiconductor, amorphous silicon, or polysilicon, but are not limited thereto. At this time, the active layers of the plurality of transistors may be formed of the same material or different materials from each other. Further, the active layers of the plurality of transistors of the gate driver may be formed of the same material as active layers of various transistors of the pixel circuit or formed of different materials from each other.

The plurality of pad areas PA1 and PA2 is areas in which a plurality of first pad electrodes PAD1 is disposed. The plurality of first pad electrodes PAD1 may transmit various signals to various wiring lines extending in a column direction in the active area AA. For example, the plurality of first pad electrodes PAD1 includes a data pad DP, a gate pad GP, a high potential power pad VP1, and a low potential power pad VP2. The data pad DP transmits a data voltage to the data line DL and the gate pad GP transmits a clock signal, a start signal, a gate low voltage, and a gate high voltage for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas PA1 and PA2 includes a first pad area PA1 located at an upper edge of the display panel PN and a second pad area PA2 located at a lower edge of the display panel PN. At this time, in the first pad area PA1 and the second pad area PA2, different types of first pad electrodes PAD1 may be disposed. For example, in the first pad area PA1, among the plurality of first pad electrodes PAD1, the data pad DP, the gate pad GP, and the high potential power pad VP1 may be disposed and in the second pad area PA2, the low potential power pad VP2 may be disposed.

At this time, the plurality of first pad electrodes PAD1 may be formed to have different sizes, respectively. For example, the plurality of data pads DP which is connected to the plurality of data lines DL one to one may have a narrower width and the high potential power pad VP1, the low potential power pad VP2, and the gate pad GP may have a larger width. However, widths of the data pad DP, the gate pad GP, the high potential power pad VP1, and the low potential power pad VP2 illustrated in FIG. 3 are illustrative so that the first pad electrode PAD1 may be configured in various sizes, but is not limited thereto.

In the meantime, to reduce the bezel of the display panel PN, an edge of the display panel PN may be cut to be removed. The plurality of pixels PX, the plurality of wiring lines, and the plurality of first pad electrodes PAD1 are formed on an initial first substrate 110i and an edge part of the initial first substrate 110i is ground to reduce the bezel area. During the grinding process, a part of the initial first substrate 110i is removed to form a first substrate 110 with a smaller size. At this time, parts of the plurality of first pad electrodes PAD1 and wiring lines disposed at the edge of the first substrate 110 may be removed. Accordingly, only a part of the plurality of first pad electrodes PAD1 may remain on the first substrate 110.

Next, the plurality of data lines DL which extends in a column direction from the plurality of first pad electrodes PAD1 is disposed on the first substrate 110 of the display panel PN. The plurality of data lines DL may extend from the plurality of data pads DP of the first pad area PA1 toward the plurality of pixel areas UPA. The plurality of data lines DL may extend in a column direction and overlap the plurality of pixel areas UPA. Therefore, the plurality of data lines DL may transmit the data voltage to the pixel circuit of each of the plurality of sub pixels SP.

The plurality of high potential power lines VL1 extending in the column direction is disposed on the first substrate 110 of the display panel PN. Some of the plurality of high potential power lines VL1 extend from the high potential power pad VP1 of the first pad area PA1 to the plurality of pixel areas UPA to transmit the high potential power voltage to the light emitting diodes 130 of the plurality of sub pixels SP, respectively. The others of the plurality of high potential power lines VL1 may be electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 may be disposed.

The plurality of low potential power lines VL2 extending in the column direction is disposed on the first substrate 110 of the display panel PN. At least some of the plurality of low potential power lines VL2 extend from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 may be electrically connected to the other low potential power line VL2 by means of an auxiliary low potential power line AVL2 to be described below.

The plurality of scan lines SL extending in the row direction is disposed on the first substrate 110 of the display panel PN. The plurality of scan lines SL may extend in the row direction and may be disposed across the plurality of pixel areas UPA and the plurality of gate driving areas GA. The plurality of scan lines SL may transmit the scan signal from the gate driver GD to the pixel circuits of the plurality of sub pixels SP.

A plurality of auxiliary high potential power lines AVL1 extending in the row direction is disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction is electrically connected to the plurality of high potential power lines VL1 extending in the column direction and may form a mesh structure. Therefore, the plurality of auxiliary high potential power lines AVL1 and the plurality of high potential power lines VL1 are configured to form a mesh structure to minimize voltage drop and voltage deviation.

A plurality of auxiliary low potential power lines AVL2 extending in the row direction is disposed on the first substrate 110 of the display panel PN. The plurality of auxiliary low potential power lines AVL2 may be disposed in an area between the plurality of pixel areas UPA. The plurality of auxiliary low potential power lines AVL2 extending in the row direction is electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize voltage deviation.

The plurality of gate driving lines GVL extending in the row direction is disposed on the first substrate 110 of the display panel PN. The plurality of gate driving lines GVL may transmit various signals to the gate driver GD of the gate driving area GA. The plurality of gate driving lines GVL may include wiring lines which transmit a clock signal, a start signal, a gate high voltage, a gate low voltage, and the like to the gate driver GD. Therefore, various signals are transmitted from the gate driving line GVL to the gate driver GD to drive the gate driver GD.

A plurality of alignment keys AK1 and AK2 is disposed in an area between the plurality of pixel areas UPA in the display panel PN. The plurality of alignment keys AK1 and AK2 is used for alignment during the manufacturing process of the display panel PN. The plurality of alignment keys AK1 and AK2 includes a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting diodes 130. For example, the first alignment key AK1 may have a cross shape, but is not limited thereto.

The second alignment key AK2 may be disposed to overlap the high potential power line VL1 between the plurality of pixel areas UPA. In the high potential power line VL1, a hole overlapping the second alignment key AK2 is formed to divide the second alignment key AK2 and the high potential power line VL1. The second alignment key AK2 may be used to align the display panel PN and a donor. The display panel PN and the donor may be aligned using the second alignment key AK2 and the plurality of light emitting diodes 130 of the donor may be transferred onto the display panel PN. For example, the second alignment key AK2 may have a circular ring shape, but is not limited thereto.

Referring to FIG. 4, the pixel circuit for driving the light emitting diode 130 is disposed in each of the plurality of sub pixels SP on the first substrate 110. The pixel circuit may include a plurality of thin film transistors and a plurality of capacitors. In FIGS. 4, for the convenience of description, only a driving transistor DT, a first capacitor C1, and a second capacitor C2, among configurations of the pixel circuit are illustrated. However, the pixel circuit may further include a switching transistor, a sensing transistor, and an emission control transistor, but is not limited thereto.

First, a light shielding layer BSM is disposed on the first substrate 110. The light shielding layer BSM blocks light which is incident to an active layer ACT of the plurality of transistors to minimize a leakage current. For example, the light shielding layer BSM is disposed below the active layer ACT of the driving transistor DT to block light incident onto the active layer ACT. If light is irradiated onto the active layer ACT, a leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), and chrome (Cr), or an alloy thereof, but is not limited thereto.

A buffer layer 111 is disposed on the light shielding layer BSM. The buffer layer 111 may reduce permeation of moisture or impurities through the first substrate 110. The buffer layer 111 may be configured by a single layer or a double layer of silicon oxide SiOx or silicon nitride SiNx, but is not limited thereto. However, the buffer layer 111 may be omitted depending on a type of the first substrate 110 or a type of the thin film transistor, but is not limited thereto.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material such as an oxide semiconductor, amorphous silicon, or polysilicon, but is not limited thereto. Further, even though it is not illustrated in the drawings, other transistors, such as a switching transistor, a sensing transistor, and an emission control transistor, other than the driving transistor DT, may be further disposed. The active layers of the transistors may be also formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control transistor, may be formed of the same material, or formed of different materials.

The gate insulating layer 112 is disposed on the active layer ACT. The gate insulating layer 112 is an insulating layer which electrically insulates the active layer ACT from the gate electrode GE and may be configured by a single layer or a double layer of silicon oxide SiOx or silicon nitride SiNx, but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), and chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact holes through which each of the source electrode SE and the drain electrode DE is connected to the active layer ACT are formed. The first interlayer insulating layer 113 and the second interlayer insulating layer 114 are insulating layers which protect components therebelow and may be configured by single layers or double layers of silicon oxide SiOx or silicon nitride SiNx, but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode 130 and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), and chrome (Cr), or an alloy thereof, but are not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a is disposed on the same layer as the light shielding layer BSM and may be formed of the same material.

The 2-2-th capacitor electrode C2b is disposed on the buffer layer 111 and the gate insulating layer 112. The 2-2-th capacitor electrode C2b is disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2c1 and a second layer C2c2. The first layer C2c1 of the 2-3-th capacitor electrode C2c may be formed on the same layer as the 1-2-th capacitor electrode C1b with the same material. The first layer C2c1 may be disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and may be connected to the first layer C2c1 through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and allow the light emitting diode 130 to emit light with a higher luminance.

A first passivation layer 115a is disposed on the driving transistor DT, the first capacitor C1, and the second capacitor C2. The first passivation layer 115a is an insulating layer which protects components below the first passivation layer 115a and may be configured by an inorganic material, such as silicon oxide SiOx or silicon nitride SiNx, but is not limited thereto.

A first planarization layer 116a is disposed on the first passivation layer 115a. The first planarization layer 116a may planarize an upper portion of the pixel circuit including the driving transistor DT. The first planarization layer 116a may be configured by a single layer or a double layer, and for example, configured by benzocyclobutene or an acrylic organic material, but is not limited thereto.

The reflection plate RF is disposed on the first planarization layer 116a. The reflection plate RF is a configuration which reflects light emitted from the plurality of light emitting diodes 130 above the first substrate 110 and may be formed with a shape corresponding to each of the plurality of sub pixels SP. One reflection plate RF may be disposed to cover the most area of one sub pixel SP. The reflection plate RF reflects the light emitted from the light emitting diode 130 and may be also used as an electrode which electrically connects the light emitting diode 130 and the pixel circuit. Specifically, the reflection plate RF may be electrically connected to the source electrode SE of the driving transistor DT and the second capacitor C2 through a first contact hole CH1 of the first planarization layer 116a and the first passivation layer 115a. The reflection plate RF may be electrically connected to the first electrode 134 of the light emitting diode 130 through the second connection electrode CE2. Therefore, the reflection plate RF may electrically connect the driving transistor DT and the first electrode 134 of the light emitting diode 130. However, the reflection plate RF may electrically connect the second electrode 135 of the light emitting diode 130 and the high potential power line VL1, instead of connecting the first electrode 134 of the light emitting diode 130 and the driving transistor DT, but is not limited thereto.

The reflection plate RF may include various conductive layers in consideration of a light reflection efficiency and a resistance. For example, the reflection plate RF may use an opaque conductive layer such as silver (Ag), aluminum (Al), molybdenum (Mo), and titanium (Ti), or an alloy thereof and a transparent conductive layer such as indium tin oxide, but the structure of the reflection plate RF is not limited thereto.

The second passivation layer 115b is disposed on the reflection plate RF. The second passivation layer 115b is an insulating layer which protects components below the second passivation layer 115b and may be configured by a single layer or a double layer of silicon oxide SiOx or silicon nitride SiNx, but is not limited thereto.

An adhesive layer AD is disposed on the second passivation layer 115b. The adhesive layer AD is formed on the entire surface of the first substrate 110 to fix the light emitting diode 130 disposed on the adhesive layer AD. The adhesive layer AD may be formed of a photo curable adhesive material which is cured by light. For example, the adhesive layer AD may be formed of an acrylic material including a photoresist, but is not limited thereto. The adhesive layer AD may be formed on the entire surface of the first substrate 110 excluding pad areas PA1 and PA2 in which the first pad electrode PAD1 is disposed.

The plurality of light emitting diodes 130 is disposed in each of the plurality of sub pixels SP on the adhesive layer AD. The light emitting diode 130 is an element which emits light by a current and may include a red light emitting diode 130 which emits red light, a green light emitting diode 130 which emits green light, and a light emitting diode 130 which emits blue light and implement light with various colors including white by a combination thereof. For example, the light emitting diode 130 may be a light emitting diode (LED) or a micro LED, but is not limited thereto.

The plurality of light emitting diodes 130 includes a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n type and p type impurities into a material such as gallium nitride (GaN), indium aluminum phosphide (InAlP), and gallium arsenide (GaAs). The p-type impurity may be magnesium (Mg), zinc (Zn), beryllium (Be), and the like, and the n-type impurity may be silicon (Si), germanium, tin (Sn), and the like, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), or the like, but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode. The first electrode 134 may be disposed on a top surface of the first semiconductor layer 131 which is exposed from the emission layer 132 and the second semiconductor layer 133. The first electrode 134 may be configured by a conductive material, for example, a transparent conductive material, such as indium tin oxide (ITO) and indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 is disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 may be an anode. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 136 which encloses the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is formed to electrically connect a first connection electrode CE1 and a second connection electrode CE2 to the first electrode 134 and the second electrode 135.

In the meantime, a part of the side surface of the first semiconductor layer 131 may be exposed from the encapsulation layer 136. The light emitting diode 130 manufactured on the wafer is separated from the wafer to be transferred onto the display panel PN. However, during the process of separating the light emitting diode 130 from the wafer, a part of the encapsulation layer 136 may be torn. For example, a part of the encapsulation layer 136 which is adjacent to a lower edge of the first semiconductor layer 131 of the light emitting diode 130 is torn during the process of separating the light emitting diode 130 from the wafer. Accordingly, a part of a lower side surface of the first semiconductor layer 131 may be exposed to the outside. However, even though the lower portion of the light emitting diode 130 is exposed from the encapsulation layer 136, the first connection electrode CE1 and the second connection electrode CE2 are formed after forming the second planarization layer 116b and the third planarization layer 116c which cover the side surface of the first semiconductor layer 131. Accordingly, a short problem may be reduced.

Next, the second planarization layer 116b and the third planarization layer 116c are disposed on the adhesive layer AD and the light emitting diode 130.

The second planarization layer 116b overlaps a part of side surfaces of the plurality of light emitting diodes 130 to fix and protect the plurality of light emitting diodes 130. The second planarization layer 116b may be formed using a halftone mask. Therefore, the second planarization layer 116b may be formed to have a step.

Specifically, a part of the second planarization layer 116b which is relatively adjacent to the light emitting diode 130 may be formed to have a smaller thickness and a part which is farther from the light emitting diode 130 may be formed to have a larger thickness. A part of the second planarization layer 116b which is adjacent to the light emitting diode 130 may be disposed to enclose the light emitting diode 130 and also may be in contact with a side surface of the light emitting diode 130. Therefore, a torn part of the encapsulation layer 136 which protects a side surface of the first semiconductor layer 131 of the light emitting diode 130 during the process of separating the light emitting diode 130 from the wafer to be transferred onto the display panel PN may be covered by the second planarization layer 116b. By doing this, contacts and short problems of the connection electrodes CE1 and CE2 and the first semiconductor layer 131 later may be suppressed.

The third planarization layer 116c is formed to cover upper portions of the second planarization layer 116b and the light emitting diode 130 and a contact hole which exposes the first electrode 134 and the second electrode 135 of the light emitting diode 130 may be formed. The first electrode 134 and the second electrode 135 of the light emitting diode 130 are exposed from the third planarization layer 116c and the third planarization layer 116c is partially disposed in an area between the first electrode 134 and the second electrode 135 to reduce a short problem. The second planarization layer 116b and the third planarization layer 116c may be configured by a single layer or a double layer, and for example, may be formed of a photoresist or an acrylic organic material, but is not limited thereto.

In the meantime, the third planarization layer 116c may cover only the light emitting diode 130 and an area adjacent to the light emitting diode 130. The third planarization layer 116c is disposed in an area of the sub pixel SP enclosed by the bank BB and may be disposed in an island shape. A bank BB is disposed in a part of the top surface of the second planarization layer 116b and the third planarization layer 116c may be disposed in the other part of the top surface of the second planarization layer 116b.

The first connection electrode CE1 and the second connection electrode CE2 are disposed on the third planarization layer 116c. The first connection electrode CE is an electrode which electrically connects the second electrode 135 of the light emitting diode 130 and the high potential power line VL1. The first connection electrode CE1 may be electrically connected to the second electrode 135 of the light emitting diode 130 through a contact hole formed in the third planarization layer 116c.

The second connection electrode CE2 is an electrode which electrically connects the first electrode 134 of the light emitting diode 130 and the driving transistor DT. The second connection electrode CE2 may be connected to the reflection plate RF of each of the plurality of sub pixels SP through contact holes formed in the third planarization layer 116c, the second planarization layer 116b, the adhesive layer AD, and the second passivation layer 115b. At this time, the reflection plate RF is also connected to the source electrode SE of the driving transistor DT so that the source electrode SE of the driving transistor DT and the first electrode 134 of the light emitting diode 130 may be electrically connected to each other.

A bank BB is disposed on the first connection electrode CE1, the second connection electrode CE2, and the second planarization layer 116b exposed from the third planarization layer 116c. The bank BB may be disposed to be spaced apart from the light emitting diode 130 with a predetermined interval and overlap at least partially the reflection plate RF. For example, the bank BB may cover a part of the second connection electrode CE2 formed in the contact holes of the third planarization layer 116c and the second planarization layer 116b. Further, for example, the bank BB may be disposed on the second planarization layer 116b with a predetermined interval from the light emitting diode 130. In this case, the bank BB and the third planarization layer 116c may be spaced apart from each other on a part of the second planarization layer 116b having a smaller thickness. That is, an end of the bank BB and an end of the third planarization layer 116c may be disposed on a part of the second planarization layer 116b having a smaller thickness formed by a halftone mask process to be spaced apart from each other.

The bank BB may be formed of an opaque material to reduce color mixture between the plurality of sub pixels SP and for example, may be formed of black resin, but is not limited thereto.

In the meantime, a thickness of a part of the bank BB which is formed in the contact holes of the third planarization layer 116c and the second planarization layer 116b to cover a part of the second connection electrode CE2 and a thickness of a part disposed on the second planarization layer 116b may be different from each other. Specifically, when the part of the bank BB covers a part of the second connection electrode CE2 formed in the contact holes of the third planarization layer 116c and the second planarization layer 116b, since the contact hole is formed from the second passivation layer 115b to the third planarization layer 116c, the bank BB may be disposed below the light emitting diode 130, that is, disposed to be lower than the light emitting diode 130. Therefore, the thickness of the part of the bank BB which covers a part of the second connection electrode CE2 formed in the contact holes of the third planarization layer 116c and the second planarization layer 116b may be larger than the thickness of a part of the bank BB disposed on the second planarization layer 116b.

A first protection layer 117 is disposed on the first connection electrode CE1, the second connection electrode CE2, and the bank BB. The first protection layer 117 is a layer for protecting components below the first protection layer 117, and may be configured by a single layer or a double layer of translucent epoxy, silicon oxide SiOx or silicon nitride SiNx, but is not limited thereto.

A plurality of first pad electrodes PAD1 is disposed in a first pad area PA1 and a second pad area PA2 of the first substrate 110. Each of the plurality of first pad electrodes PAD1 may be configured by a plurality of conductive layers. For example, each of the plurality of first pad electrodes PAD1 includes a first conductive layer PE1a, a second conductive layer PE1b, and a third conductive layer PE1c.

First, the first conductive layer PE1a is disposed on the second interlayer insulating layer 114. The first conductive layer PE1a may be formed of the same conductive material as the source electrode SE and the drain electrode DE and for example, may be configured by copper (Cu), aluminum (Al), molybdenum (Mo), nickel (Ni), titanium (Ti), chrome (Cr), or an alloy thereof, but is not limited thereto.

The first passivation layer 115a is disposed on the first conductive layer PE1a and the second conductive layer PE1b is disposed on the first passivation layer 115a. The second conductive layer PE1b may be formed of the same conductive material as the reflection plate RF and for example, may be configured by silver (Ag), aluminum (Al), molybdenum (Mo), or an alloy thereof, but is not limited thereto.

The third conductive layer PE1c is disposed on the second conductive layer PE1b. The third conductive layer PE1c may be formed of the same conductive material as the first connection electrode CE1 and the second connection electrode CE2, and for example, a transparent conductive material, such as indium tin oxide (ITO) or indium zinc oxide (IZO), but is not limited thereto.

At this time, even though it is not illustrated in the drawings, some of the plurality of conductive layers of the first pad electrode PAD1 are electrically connected to a plurality of wiring lines on the first substrate 110 to supply various signals to a plurality of wiring lines and a plurality of sub pixels SP. For example, the first conductive layer PE1a and/or the second conductive layer PE1b of the first pad electrode PAD1 is connected to the data line DL, the high potential power line VL1, and the low potential power line VL2 disposed in the active area AA to transmit signals thereto.

A first metal layer ML1, a second metal layer ML2, and a plurality of insulating layers may be disposed together below the first pad electrode PAD1. The first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110. The first metal layer ML1 may be formed of the same conductive material as the gate electrode GE and the second metal layer ML2 may be formed of the same conductive material as a 1-2-th capacitor electrode C1b. However, the plurality of insulating layers, the first metal layer, and the second metal layer below the first pad electrode PAD1 may be omitted depending on a design and are not limited thereto.

A second substrate 120 is disposed below the first substrate 110. The second substrate 120 is a substrate which supports components disposed below the display device 100 and may be an insulating substrate. For example, the second substrate 120 may be formed of glass, resin, or the like. Further, the second substrate 120 may include polymer or plastic. The second substrate 120 may be formed of the same material as the first substrate 110. In some exemplary aspects, the second substrate 120 may be formed of a plastic material having flexibility.

A bonding layer BDL is disposed between the first substrate 110 and the second substrate 120. The bonding layer BDL may be formed of a material which is cured by various curing methods to bond the first substrate 110 and the second substrate 120. The bonding layer BDL may be disposed only in a partial area between the first substrate 110 and the second substrate 120 or may be disposed in the entire area.

A plurality of second pad electrodes PAD2 is disposed on a rear surface of the second substrate 120. The plurality of second pad electrodes PAD2 is electrodes which transmit a signal from a driving component disposed on the rear surface of the second substrate 120 to a plurality of side lines SRL and a plurality of first pad electrodes PAD1 and a plurality of wiring lines on the first substrate 110. The plurality of second pad electrodes PAD2 is disposed in an end portion of the second substrate 120 in the non-active area NA to be electrically connected to the side line SRL which covers the end portion of the second substrate 120.

At this time, the plurality of second pad electrodes PAD2 may be also disposed to correspond to the plurality of pad areas PA1 and PA2. The plurality of first pad electrodes PAD1 may be disposed to correspond to the plurality of second pad electrodes PAD2, respectively, and then the first pad electrode PAD1 and the second pad electrode PAD2 which overlap each other may be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

First, the fourth conductive layer PE2a is disposed below the second substrate 120. The fourth conductive layer PE2a may be configured by a conductive material such as copper (Cu), aluminum (Al), molybdenum (Mo), nickel (Ni), titanium (Ti), chrome (Cr), or an alloy thereof, but is not limited thereto.

The fifth conductive layer PE2b is disposed below the fourth conductive layer PE2a. The fifth conductive layer PE2b may be configured by a conductive material, such as copper (Cu), aluminum (Al), molybdenum (Mo), nickel (Ni), titanium (Ti), chrome (Cr), or an alloy thereof, but is not limited thereto.

The sixth conductive layer PE2c is disposed below the fifth conductive layer PE2b. The sixth conductive layer PE2c may be formed of a conductive material, for example, a transparent conductive material, such as indium tin oxide (ITO) or indium zinc oxide (IZO), but is not limited thereto.

The second protection layer 121 is disposed in the remaining area of the second substrate 120. The second protection layer 121 may protect various wiring lines and driving components formed on the second substrate 120. The second protection layer 121 may be configured by an organic insulating material, and for example, configured by benzocyclobutene or an acrylic organic insulating material, but is not limited thereto.

Even though it is not illustrated in the drawing, a driving component including a plurality of flexible films and a printed circuit board may be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

For example, the fourth conductive layer PE2a and/or the fifth conductive layer PE2b of the second pad electrode PAD2 extend to the plurality of flexible films disposed on the rear surface of the second substrate 120 to be electrically connected to the plurality of flexible films. The plurality of flexible films may supply various signals to the plurality of side lines SRL, the plurality of first pad electrodes PAD1, the plurality of wiring lines, and the plurality of sub pixels SP through the second pad electrode PAD2. Therefore, the signal from the driving component may be transmitted to the signal line and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL is disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed to enclose the side surface of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL may be formed by a pad printing method using a conductive ink, for example, including silver (Ag), copper (Cu), molybdenum (Mo), and chrome (Cr).

A side insulating layer 140 which covers the plurality of side lines SRL is disposed. The side insulating layer 140 may be formed on the top surface of the first substrate 110, the side surface of the first substrate 110, the side surface of the second substrate 120, and the rear surface of the second substrate 120 to cover the side line SRL. The side insulating layer 140 may protect the plurality of side lines SRL.

In the meantime, when the plurality of side lines SRL is formed of a metal material, there may be a problem in that external light is reflected from the plurality of side lines SRL or light emitted from the light emitting diode 130 is reflected from the plurality of side lines SRL to be visibly recognized by the user. Therefore, the side insulating layer 140 is configured to include a black material to suppress reflection of the external light. For example, the side insulating layer 140 may be formed by a pad printing method using an insulating material including a black material, for example, a black ink.

A seal member 150 which covers the side insulating layer 140 is disposed. The seal member 150 is disposed to enclose the side surface of the display device 100 to protect the display device 100 from external impacts, moisture, oxygen, and the like. For example, the seal member 150 may be formed of polyimide (PI), poly urethane, epoxy, or acryl based insulating material, but is not limited thereto.

An optical film MF is disposed on the seal member 150, the side insulating layer 140, and the first protection layer 117. The optical film MF may be a functional film which implements a higher quality of images while protecting the display device 100. For example, the optical film MF may include an anti-scattering film, an anti-glare film, an anti-reflecting film, a low-reflecting film, an Oled transmittance controllable film, a polarizer, or the like, but is not limited thereto.

In the meantime, an edge of the seal member 150 and an edge of the optical film MF may be disposed on the same line. The optical film MF having a larger size is attached above the first substrate 110 during the manufacturing process of the display device 100 and the seal member 150 which covers the side insulating layer 140 may be formed. Thereafter, laser is irradiated on the seal member 150 and the optical film MF to correspond to an edge of the display device 100 to cut a part of the seal member 150 and the optical film MF. Accordingly, the size of the display device 100 is adjusted by an outer periphery cutting process of the seal member 150 and the optical film MF and the edge of the display device 100 may be formed to be flat.

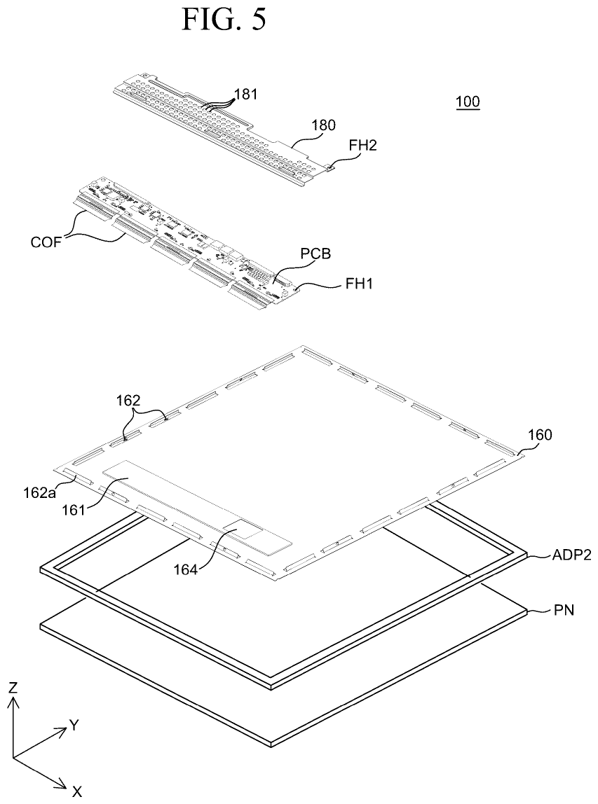

Hereinafter, a mechanical structure of the display device 100 according to the exemplary aspect of the present disclosure will be described with reference to FIGS. 5 to 8.

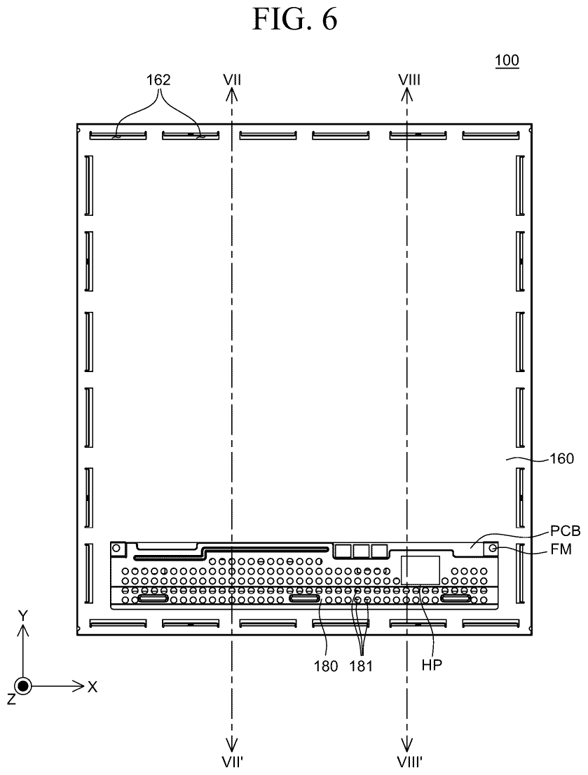

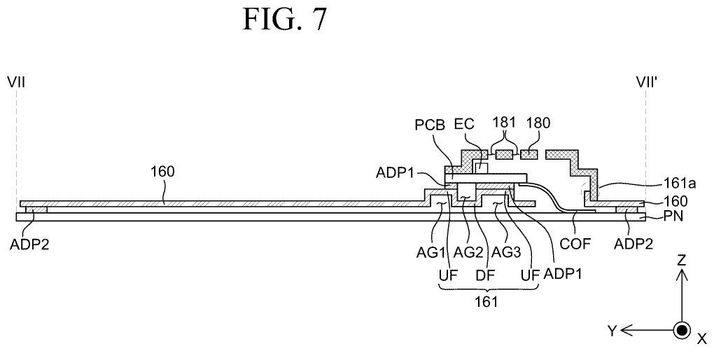

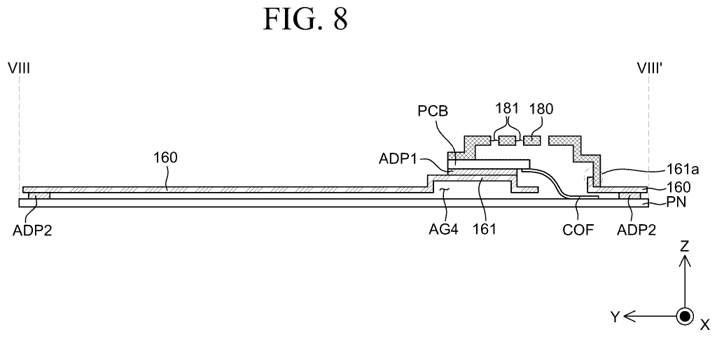

FIG. 5 is an exploded perspective view of a display device according to an exemplary aspect of the present disclosure. FIG. 6 is a rear view of a display device according to an exemplary aspect of the present disclosure. FIG. 7 is a cross-sectional view taken along line VII-VII′ of FIG. 6. FIG. 8 is a cross-sectional view taken along line VIII-VIII′ of FIG. 6.

Referring to FIGS. 5 to 7, the display device 100 according to the exemplary aspect of the present disclosure includes a display panel PN, a flexible film COF, a printed circuit board PCB, a cover bottom 160, a cover shield 180, and a second adhesive member ADP2.

A plurality of flexible films COF is bonded onto a rear surface of the display panel PN. The plurality of flexible films COF may be electrically connected to the plurality of second pad electrodes PAD2 of the second substrate 120 of the display panel PN. The flexible film COF is a film in which various components are disposed on a base film having a ductility to supply a signal to the sub pixel SP and a driving component and may be electrically connected to the display panel PN.

A driving IC such as a gate driver IC or a data driver IC may be disposed on the plurality of flexible films COF. The driving IC is a component which processes data for displaying images and a driving signal for processing the data. The driving IC may be disposed in a chip on glass (COG), a chip on film (COF), or a tape carrier package (TCP) manner depending on a mounting method. However, for the convenience of description, it is described that the driving IC is mounted on the plurality of flexible films COF by a chip on film technique, but is not limited thereto.

The printed circuit board PCB is electrically connected to the plurality of flexible films COF. The printed circuit board PCB is a component which supplies signals to the driving IC. On the printed circuit board PCB, various components for supplying various signals to the driving IC may be disposed.

The printed circuit board PCB may include a plurality of elements to drive the display panel PN. The plurality of elements may be configured by various IC chips. For example, on the printed circuit board PCB, an element used to generate various voltages, such as a high potential power, a low potential power, and a reference power, that is, an IC chip may be disposed. In the meantime, when the display device 100 is driven, heat may be generated from the element disposed on the printed circuit board PCB. Specifically, an element, such as an IC FET or a buck IC which generates a high potential voltage, like a power management integrated circuit (PMIC), may generate the highest heat, among various chips disposed on the printed circuit board PCB. Therefore, the highest heat is generated in an area in which an element such as PMIC is disposed, among the areas in which the printed circuit board PCB is disposed, so that an overall temperature deviation of the display panel PN may be increased. When there is a temperature deviation in each area of the display panel PN, spots may be seen from the display panel PN, a color difference may occur, or a display quality may be degraded. Hereinafter, a position of the area in which the printed circuit board PCB is disposed overlapping an element which generates the highest heat is assumed as a heat area HP and the element EC is assumed as an element which generates the highest heat.

In the meantime, even though in FIG. 5, it is illustrated that five flexible films COF and one printed circuit board PCB are provided, the number of the plurality of flexible films COF and printed circuit boards PCB may vary depending on a design, but is not limited thereto.

The printed circuit board PCB includes a first fastening hole FH1. A fastening member FM is inserted into the first fastening hole FH1 formed in the printed circuit board PCB so that the printed circuit board PCB and the cover shield 180 may be fastened with each other.

A cover bottom 160 is disposed on a rear surface of the display panel PN. The cover bottom 160 may support and protect the display panel PN from the rear surface of the display panel PN. The cover bottom 160 is formed to have a shape corresponding to a planar shape of the display panel PN to cover the display panel PN. The cover bottom 160 may be formed of a material having a rigidity and a high thermal conductivity and for example, may be formed of a metal material such as aluminum (Al), copper (Cu), zinc (Zn), silver (Ag), gold (Au), iron (Fe), steel use stainless (SUS), invar, and a plastic material.

The cover bottom 160 includes a plurality of openings 162. The plurality of openings 162 of the cover bottom 160 is disposed along an edge of the cover bottom 160. The plurality of openings 162 may be disposed to be parallel to the edge of the cover bottom 160. The plurality of openings 162 has a plurality of protrusions 162a.

The plurality of protrusions 162a is parts which couple the display device 100 to a cabinet. The plurality of protrusions 162a is used to fix the display device 100 to the cabinet in the form of a tile to form a tiling display device TD. The plurality of protrusions 162a is formed by bending a part of the cover bottom 160 in a direction perpendicular to the rear surface of the cover bottom 160 and may have an L-shaped cross-sectional shape.

The protrusion 162a may be formed by cutting and bending a part of the cover bottom 160. Therefore, when the plurality of protrusions 162a is formed, the plurality of openings 162 may be formed in a part in which the cover bottom 160 is cut. Therefore, the protrusions 162a may be disposed on the edges of the plurality of openings 162. For example, the protrusion 162a may be disposed on an edge of the opening 162 which is parallel to an edge of the cover bottom

The cover bottom 160 may include a forming unit (or heat dissipating portion) 161 that accommodates an air gap for effectively dissipating heat generated inside the display device or heat generated from the element EC.

The forming unit 161 of the cover bottom 160 is disposed to correspond to the printed circuit board PCB. The printed circuit board PCB is disposed on the forming unit 161. That is, the printed circuit board PCB may be disposed on an up-forming unit UF (or upwardly protruding portion) and a down-forming unit DF (or downwardly protruding portion) of the cover bottom 160. Even though it is not illustrated, the forming unit 161 and the printed circuit board PCB may be bonded face to face by an adhesive member. That is, the adhesive member is disposed between the printed circuit board PCB and the forming unit 161 of the cover bottom 160 and the forming unit 161 and the printed circuit board PCB may be bonded by the adhesive member. At this time, a bonding area between the forming unit 161 and the printed circuit board PCB may be adjusted differently according to the forming position of the forming unit 161 and the position of the printed circuit board PCB.

The forming unit 161 may be disposed to protrude to a direction perpendicular to the rear surface of the cover bottom 160, for example, a Z-axis direction. In other words, the forming unit 161 of the cover bottom 160 is a convexly protruding portion of the cover bottom 160.

The forming unit 161 may be disposed in a predetermined area provided at one side of the cover bottom 160. The forming unit 161 is disposed to be adjacent to any one of four sides of the cover bottom 160 and the printed circuit board PCB and the cover shield 180 may be disposed to correspond to the corresponding area.

Here, the printed circuit board PCB and the cover shield 180 may be coupled by a fastening member FM which passes through a first fastening hole FH1 and a second fastening hole FH2 provided therein. In contrast, the printed circuit board PCB and the cover bottom 160 may be coupled to each other by a first adhesive member ADP1. The first adhesive member ADP1 may be a double-sided tape having adhesiveness, but is not limited thereto. As described above, in the case of the display device according to the exemplary aspect, the printed circuit board PCB and the cover bottom 160 are bonded by the first adhesive member ADP1 to reduce the number of fastening members FM used for manufacturing. Therefore, a display device with excellent quality may be manufactured with a reduced cost.

The forming unit 161 may overlap at least a part of an area in which the plurality of flexible films COF and/or the printed circuit board PCB is disposed, in the entire area of the display panel PN. The forming unit 161 may be disposed to protrude toward a direction perpendicular to a rear surface of the display panel PN. Therefore, an empty space may be formed between the forming unit 161 and the display panel PN. In the present disclosure, the empty space may be referred to as an “air gap” or an “air layer”. As the printed circuit board PCB is disposed on the forming unit 161 which forms the air gaps AG1, AG2, AG3, and AG4, the air gaps AG1, AG2, AG3, and AG4 may be disposed below the printed circuit board PCB. The air gaps AG1, AG2, AG3, and AG4 may block the diffusion of the heat generated from the printed circuit board PCB or diffuse the heat to the surroundings.

Referring to FIG. 7, a cross-section including the heat area HP taken along line VIII-VIII′ will be described as an example. Referring to FIG. 7, the forming unit 161 in the heat area HP may include an up-forming unit UF and a down-forming unit DF which is enclosed by the up-forming unit UF. The up-forming unit UF may have a shape protruding along a rear surface direction, that is, the Z-axis direction and the down-forming unit DF may have a shape which is recessed by a predetermined depth along a front surface direction from the top surface of the up-forming unit UF1, for example, a −Z-axis direction. Accordingly, an interval between the up-forming unit UF1 and the display panel PN may be larger than the interval between the down-forming unit DF and the display panel PN. The cover bottom 160 may form an additional air gap not only at a portion connected to the display panel PN by means of the second adhesive member ADP2, but also over the remaining area.

The up-forming unit UF, the down-forming unit DF, the printed circuit board PCB, and the display panel PN are disposed to enclose a plurality of air gaps. For example, a first air gap AG1 and a third air gap AG3 may be formed between the up-forming unit UF and the display panel PN and a second gap AG2 may be formed between the down-forming unit DF and the printed circuit board PCB. Even though in FIG. 7, it is illustrated that the first air gap AG1 and the third air gap AG3 are separated, actually, the first air gap AG1 and the third air gap AG3 are connected as one air gap to circulate heat. That is, the first air gap AG1 and the third air gap AG3 are integrated to form an air gap and the first air gap AG1 and the third air gap AG3 may be formed to have a larger area or width than that of the second air gap AG2. Further, the second air gap AG2 at least partially overlaps the element EC to block heat caused by the element EC.

In the meantime, the forming unit 161 is formed between the second air gap AG2 and the first air gap AG1 and between the second air gap AG2 and the third air gap AG3 to serve as a partition. The second air gap AG2 is formed between the printed circuit board PCB and the cover bottom 160 to block the heat generated from the element EC of the printed circuit board PCB from being directed to the display panel PN.

As described above, in the display device 100 according to the exemplary aspect of the present disclosure, the first air gap AG1 and the third air gap AG3 between the display panel PN and the cover bottom 160 and the second air gap AG2 between the cover bottom 160 and the printed circuit board PCB are formed. Accordingly, the influence on the display panel PN due to the heat generated in the element EC of the printed circuit board PCB may be reduced.

Next, referring to FIG. 8, a cross section in an area other than the heat area HP will be described with reference to the cross-sectional view taken along line XIII-XIII′. The forming unit 161 in the remaining area has a protruding shape along the rear surface direction of the cover bottom 160, for example, the Z-axis direction, and may not form a down-forming unit.

The forming unit 161 may form an air gap. For example, the fourth air gap AG4 may be formed between the forming unit 161 and the display panel PN. The fourth air gap AG4 may be connected to the first air gap AG1 and the third air gap AG3. Air circulating through the first air gap AG1 and the third air gap AG3 may be continued to the fourth air gap AG4.

The fourth air gap AG4 may have a width larger than that of the first air gap AG1 or the third air gap AG3, that is, may be formed as a width in the Y-axis direction. As the fourth air gap AG4 is formed with a larger width, the heat may be widely diffused to the fourth air gap AG4 via the first air gap AG1 or the third air gap AG3. The fourth air gap AG4 may be formed to have a width larger than a sum of widths of the first air gap AG1 and the third air gap AG3.

The cover bottom 160 may disperse and dissipate the heat generated in the printed circuit board PCB. Further, the cover bottom 160 does not allow the printed circuit board PCB to be in direct contact with the display panel PN to minimize the concentration of the heat of the printed circuit board PCB on a specific area of the display panel PN. The cover bottom 160 disperses the heat generated in the printed circuit board PCB to the entire cover bottom 160 so as not to concentrate the heat on a partial area of the display panel PN adjacent to the driving chip and may reduce the entire temperature deviation of the display panel PN.

The cover shield 180 may be disposed on the cover bottom 160 and the printed circuit board PCB. The cover shield 180 may protect the printed circuit board PCB from the external impact. The cover shield 180 is formed of a material having a rigidity to protect the printed circuit board PCB, but is not limited thereto.

The cover shield 180 may be disposed on the cover bottom 160 to cover the printed circuit board PCB on the rear surface. One edge of the cover shield 180 is bent in an L-shape and may be in contact with one side surface (for example, an outer side surface) of the protrusion 161a of the cover bottom 160. Therefore, the protrusion 161a and one side portion of the cover shield 180 are engaged with each other to restrict the movement of the cover shield 180 and guide the position of the cover shield 180.

The cover shield 180 includes a plurality of dissipation holes 181. The plurality of dissipation holes 181 may be disposed in the most area of the cover shield 180. The plurality of dissipation holes 181 is formed to dissipate the heat generated in the printed circuit board PCB to the outside of the cover shield 180. Some driving chips which generate a lot of heat, among the plurality of components of the printed circuit board PCB, may be exposed from the cover shield 180. Some driving chips which generate a lot of heat are exposed from the cover shield 180 to efficiently dissipate heat generated in the driving chips. Therefore, additional grooves or holes may be formed in a part of the cover shield 180 according to a position of the driving chip which generates a lot of heat.

The cover shield 180 includes a plurality of second fastening holes FH2. A fastening member FM is inserted into the second fastening hole FH2 to fix the cover shield 180 to the printed circuit board PCB. Specifically, the cover shield 180 and the printed circuit board PCB may be fixed to each other through the fastening member FM which passes through both the second fastening hole FH2 of the cover shield 180 and the first fastening hole FH1 of the printed circuit board PCB. As described above, a combination configured by the cover shield 180 and the printed circuit board PCB may be bonded to the cover bottom 160 by means of a first adhesive member ADP1. The first adhesive member ADP1 may be disposed on the forming unit 161 of the cover bottom 160 and the combination may be bonded onto the forming unit 161 face to face. Specifically, the first adhesive member ADP1 may bond the up-forming unit UF and the printed circuit board PCB and may be disposed to be spaced apart from the down-forming unit DF. That is, the first adhesive member ADP1 may be in contact with only the up-forming unit UF of the forming unit 161.

A second adhesive member ADP2 is disposed between the cover bottom 160 and the display panel PN. The second adhesive member ADP2 may be formed of a material with adhesiveness to fix the cover bottom 160 onto the rear surface of the display panel PN. The second adhesive member ADP2 may be disposed along an edge of the display panel PN and an edge of the cover bottom 160. The second adhesive member ADP2 may be formed in a frame shape corresponding to an edge of the display panel PN. For example, the second adhesive member ADP2 may be a foam tape having adhesiveness, but is not limited thereto.

The second adhesive member ADP2 is disposed to be adjacent to an edge of the cover bottom 160 and may overlap an opening 162 of the cover bottom 160. The opening 162 of the cover bottom 160 may overlap the second adhesive member ADP2. The opening 162 is formed to overlap the second adhesive member ADP2 and an area in which the heat is directly transmitted from the display panel PN to the cover bottom 160 through the second adhesive member ADP2 may be reduced.

In the meantime, a separate plate bottom may be used to support the printed circuit board. When the separate plate bottom is used, a fixing structure which fixes the printed circuit board to the plate bottom is required. Further, the plate bottom needs to be formed separately from the cover bottom so that the manufacturing process may become complex and a manufacturing cost may be increased.

Accordingly, in the display device 100 according to an exemplary aspect of the present disclosure, a separate plate bottom is not used, but a single cover bottom 160 is used between the printed circuit board PCB and the display panel PN. Therefore, the printed circuit board PCB and the display panel PN are supported by one mechanical device to reduce the manufacturing cost and a cost for an assembling process.

Further, in the display device 100 according to an exemplary aspect of the present disclosure, the printed circuit board PCB and the cover bottom 160 are bonded using a first adhesive member ADP1 such as a double-sided tape, without using a fastening member such as a pem nut. Accordingly, the manufacturing process may be simplified and the manufacturing cost may be also reduced.

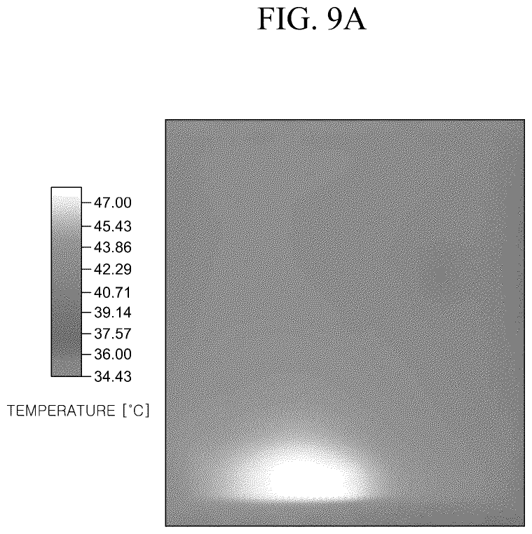

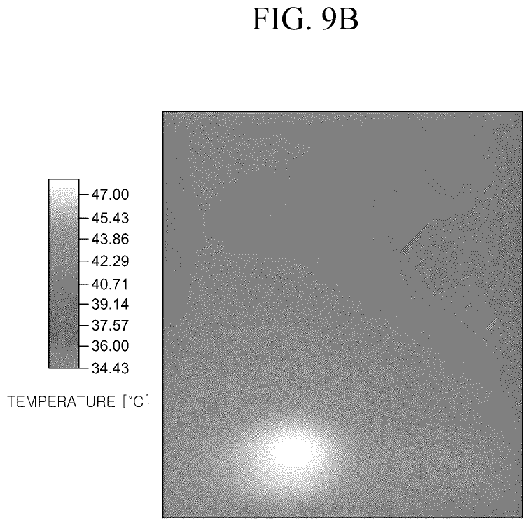

Hereinafter, P an effect of reducing a temperature deviation of a display panel by a forming unit will be described with reference to FIGS. 9A and 9B.

FIG. 9A is a temperature measurement result of a display device according to a comparative aspect. FIG. 9B is a temperature measurement result of a display device according to an exemplary aspect of the present disclosure. A display device according to a comparative aspect has the same structure as the display device 100 according to the exemplary aspect of the present disclosure except that the forming unit 161 is not provided, the printed circuit board PCB is directly disposed on the cover bottom 160, and the cover bottom 160 extends to be flat on the display panel PN. In FIGS. 9A and 9B, the temperature measurement is a result of measuring a temperature on front surfaces of the display devices while driving the display device according to the comparative aspect and the display device 100 according to the exemplary aspect of the present disclosure. A lighter color of the image indicates a higher temperature and a darker color indicates a lower temperature.

In the display device according to the comparative aspect and the display device 100 according to the exemplary aspect of the present disclosure, a maximum temperature was measured in a position in which an element emitting highest heat was disposed. At this time, in the display device according to the comparative aspect, the highest temperature was 47.20° C., the lowest temperature was 35.47° C., and an average temperature was 41.37° C. In the display device 100 according to the exemplary aspect of the present disclosure, the highest temperature was 47.15° C., the lowest temperature was 35.46° C., and an average temperature was 39.90° C. Accordingly, in the display device 100 according to the exemplary aspect of the present disclosure, the highest temperature was reduced by 0.05° C. and the average temperature was reduced by 1.47° C., as compared with the display device according to the comparative aspect.

In the display device according to the comparative aspect, the forming unit of the cover bottom is not provided so that it is difficult to ensure a space in which the air circulates in the most area between the display panel and the cover bottom. Accordingly, the heat generated from the printed circuit board in a lower area of the display panel is not diffused to the remaining area of the display panel, but is concentrated on only the lower area of the display panel so that the overall temperature deviation of the display panel may be increased. When there is a temperature deviation in each area of the display panel, spots may be seen from the display panel, a color difference may occur, or a display quality may be degraded.

In contrast, in the display device 100 according to the exemplary aspect of the present disclosure, it is confirmed that the average temperature is significantly reduced as compared with the display device according to the comparative aspect. In the cover bottom 160, a forming unit 161 which provides an air gap to circulate air is formed to easily diffuse the heat generated in the lower area of the display panel PN to an intermediate area and an upper area of the display panel PN and implement uniformly the entire temperature of the display panel PN.

Further, in the display device 100 according to the exemplary aspect of the present disclosure, the forming unit 161 includes the up-forming unit UF and the down-forming unit DF to dispose the second air gap AG2 between a portion of the printed circuit board PCB in which an clement EC emitting the highest heat is disposed and the cover bottom 160. Accordingly, the heat from the element EC emitting the highest heat is suppressed from being directly transmitted to the display panel PN through the cover bottom 160 to reduce a highest temperature and an average temperature of the display panel PN.

The exemplary aspects of the present disclosure may also be described as follows:

According to an aspect of the present disclosure, a display device comprises a display panel; a cover bottom disposed on a rear surface of the display panel; and a printed circuit board disposed on a rear surface of the cover bottom and includes a plurality of elements to drive the display panel, wherein the cover bottom including a forming unit disposed in a predetermined area of the cover bottom, and the printed circuit board may be disposed on the up-forming unit and the down-forming unit, and one or more air gaps are formed between the forming unit and the display panel and/or the printed circuit board.

The predetermined area overlaps at least a part of an area in the display panel in which a plurality of flexible films and/or the printed circuit board PCB is disposed

The forming unit is disposed to protrude toward a direction perpendicular to a rear surface of the display panel.

In a part of the forming unit, the forming unit includes an up-forming unit and a down-forming unit which is enclosed by the up-forming unit, the up-forming unit has a shape protruding along a rear surface direction of the display panel and the down-forming unit has a shape which is recessed by a predetermined depth along a front surface direction of the display panel from the top surface of the up-forming unit, so that the up-forming unit, the down-forming unit, the printed circuit board, and the display panel may be disposed to enclose a plurality of air gaps.

The plurality of air gaps may include a first air gap and a third air gap disposed between the up-forming unit and the display panel; and a second air gap disposed between the down-forming unit and the printed circuit board, and the first air gap and the third air gap may be disposed in a broader area than that of the second air gap and the second air gap may be disposed in a position at least partially overlapping some of the plurality of elements.

The second air gap may be disposed in a position overlapping an element generating highest heat, among the plurality of elements.

A part of the cover bottom overlapping the element generating highest heat may be spaced apart from the printed circuit board.

The element which generates highest heat may be a power management integrated circuit (PMIC).

The second air gap and the first air gap as well as the third air gap and the second air gap may be separated by the cover bottom.

An interval between the up-forming unit and the display panel may be larger than an interval between the down-forming unit and the display panel.

The display device may further comprise an adhesive member bonding the up-forming unit and the printed circuit board.

The adhesive member may be disposed to be spaced apart from the down-forming unit.

The display device according to claim 4, wherein in other part of the forming unit, the forming unit includes only an up-forming unit, a fourth air gap is formed between the up-forming unit and the display panel to communicate with the first air gap and the third air gap, and the width of the fourth air gap is larger than the first air gap or the third air gap.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. All the technical concepts in the equivalent scope of the present disclosure should be construed as falling within the scope of the present disclosure.

What is claimed is:

1. A display device, comprising:
a display panel;
a cover bottom disposed on a rear surface of the display panel; and
a printed circuit board disposed on a rear surface of the cover bottom and including a plurality of elements to drive the display panel,
wherein the cover bottom includes a heat dissipating portion disposed in the cover bottom, and the printed circuit board is disposed on the heat dissipating portion, and one or more air gaps are formed between the heat dissipating portion and at least one of the display panel and the printed circuit board.

2. The display device according to claim 1, wherein the heat dissipating portion overlaps a part of the display panel in which a plurality of flexible films and/or the printed circuit board is disposed.

3. The display device according to claim 1, wherein the heat dissipating portion is disposed to protrude toward a direction perpendicular to the rear surface of the display panel.

4. The display device according to claim 1, wherein the heat dissipating portion includes an upwardly protruding portion extending to a direction away from the rear surface of the display panel and a downwardly protruding portion extending to a direction towards to the rear surface of the display panel, and
wherein the upward portion, the upward portion, the printed circuit board, and the display panel accommodate a plurality of air gaps.

5. The display device according to claim 4, wherein the plurality of air gaps includes:
a first air gap and a third air gap disposed between the upwardly protruding portion and the display panel; and
a second air gap disposed between the downwardly protruding portion and the printed circuit board, and
wherein the first air gap and the third air gap are disposed in a broader area than that of the second air gap and the second air gap is disposed in a position at least partially overlapping some of a plurality of elements.

6. The display device according to claim 5, wherein the second air gap is disposed in a position overlapping a highest heat generating element among the plurality of elements.

7. The display device according to claim 6, wherein a part of the cover bottom overlapping the highest heat generating element is spaced apart from the printed circuit board.

8. The display device according to claim 6, wherein the highest heat generating element includes a power management integrated circuit (PMIC).

9. The display device according to claim 5, wherein the first and second air gaps are separated by the cover bottom, and the second and third air gaps are separated by the cover bottom.

10. The display device according to claim 4, wherein an interval between the upwardly protruding portion and the display panel is larger than an interval between the downwardly protruding portion and the display panel.

11. The display device according to claim 4, further comprising an adhesive member bonding the upwardly protruding portion and the printed circuit board.

12. The display device according to claim 11, wherein the adhesive member is spaced apart from the downwardly protruding portion.

13. The display device according to claim 1, wherein the heat dissipating portion includes only an upwardly protruding portion extending to a direction away from the rear surface of the display panel, and an air gap formed between the upwardly protruding portion and the display panel.

14. A display device, comprising:
a display panel;
a cover bottom disposed on the display panel; and
a printed circuit board disposed on the cover bottom,
wherein the cover bottom includes a convex portion protruding towards the printed circuit board, and the convex portion accommodates at least one air gap.

15. The display device according to claim 14, further comprising a cover shield disposed on the printed circuit board and the cover bottom.

16. The display device according to claim 15, wherein the cover shield includes a plurality of heat dissipation holes.

17. The display device according to claim 15, wherein the cover shield and the cover bottom accommodate an air gap.

18. The display device according to claim 15, wherein the cover shield has a first edge engaged with a side portion of the cover bottom and a second edge in contact with the printed circuit board.

19. A display device, comprising:
a display panel;
a cover bottom disposed on the display panel;
a printed circuit board disposed on the cover bottom; and
a highest heat generating element disposed on the printed circuit board,
wherein the cover bottom includes at least one of a convex portion protruding towards the printed circuit board and a concave portion protruding towards the display panel, and each of the convex portion and the concave portion accommodates an air gap.

20. The display device according to claim 16, wherein the printed circuit board, the cover bottom, and the display panel are attached with one another through an adhesive member.
